(19) United States
(12) Patent Application Publication
(10) Pub. No.: US 2006/0028194 A1
(43) Pub. Date: Feb. 9, 2006

(54) ELECTRONIC VOLTAGE POLARITY TEST PROBE

(75) Inventor: Warren Bosch, Ashburn, VA (US)

Correspondence Address: OBLON, SPIVAK, MCCLELLAND, MAIER & NEUSTADT, P.C., 1940 DUKE STREET, ALEXANDRIA, VA, 22314, US

(73) Assignee: DESIGNTECH INTERNATIONAL, INC., Springfield, VA (US)

(21) Appl. No.: 10/913,351

(22) Filed: Aug. 9, 2004

(51) Int. Cl. G01R 31/02

(52) U.S. Cl. 324/72.5

(57) ABSTRACT

An electronic voltage polarity indicator that provides an easy to identify indication as to whether an electrical surface being contacted by a probe is at a positive or negative polarity. The electronic voltage polarity indicator is particularly useable with a 12 volt power source, and thus can find application in the installation of equipment in vehicles, such as automobiles.

### BACKGROUND OF THE INVENTION

1. Field of the Invention

The present invention is directed to an electronic voltage polarity indicator that can be utilized in a vehicle environment for testing whether an electrical surface is at a positive or negative polarity, and to evaluate connectivity of low impedance.

2. Discussion of the Background

Instances often arise in which a person may want to determine whether an electrical surface has a positive or negative polarity. One common such instance is when installing components into a vehicle, such as an automobile. For example, if a remote vehicle starter or other automotive after market accessories are being installed into an automobile, it becomes helpful to be able to identify “dead” or “live” circuits, and instantly identified test point as being either positive or negative in polarity

Other examples in which it may be desired to determine whether an electrical surface has a positive or a negative polarity is when testing door pin switches, lights, fuses, computer inputs/outputs, and distributors.

### SUMMARY OF THE INVENTION

One object of the present invention is to provide a novel electronic voltage polarity indicator for use with vehicles that can indicate whether a contacted electrical surface has a positive or negative polarity, and to evaluate connectivity of low impedance circuits.

A further object of the present invention is to provide such a novel electronic voltage polarity indicator in a device that is simple and safe to use, and that provides a clear and efficient display.

### BRIEF DESCRIPTION OF THE DRAWINGS

A more complete appreciation of the present invention and many of the attendant advantages thereof will be readily obtained as the same becomes better understood by reference to the following detailed description when considered in connection with the accompanying drawings, wherein:

FIG. 1 shows a first embodiment of an electronic voltage polarity indicator of the present invention from an external view;

FIG. 2 shows circuitry included in the electronic voltage polarity indicator of FIG. 1; and

FIG. 3 shows a second embodiment of an electronic voltage polarity indicator of the present invention from an external view.

### DETAILED DESCRIPTION OF THE PREFERRED EMBODIMENTS

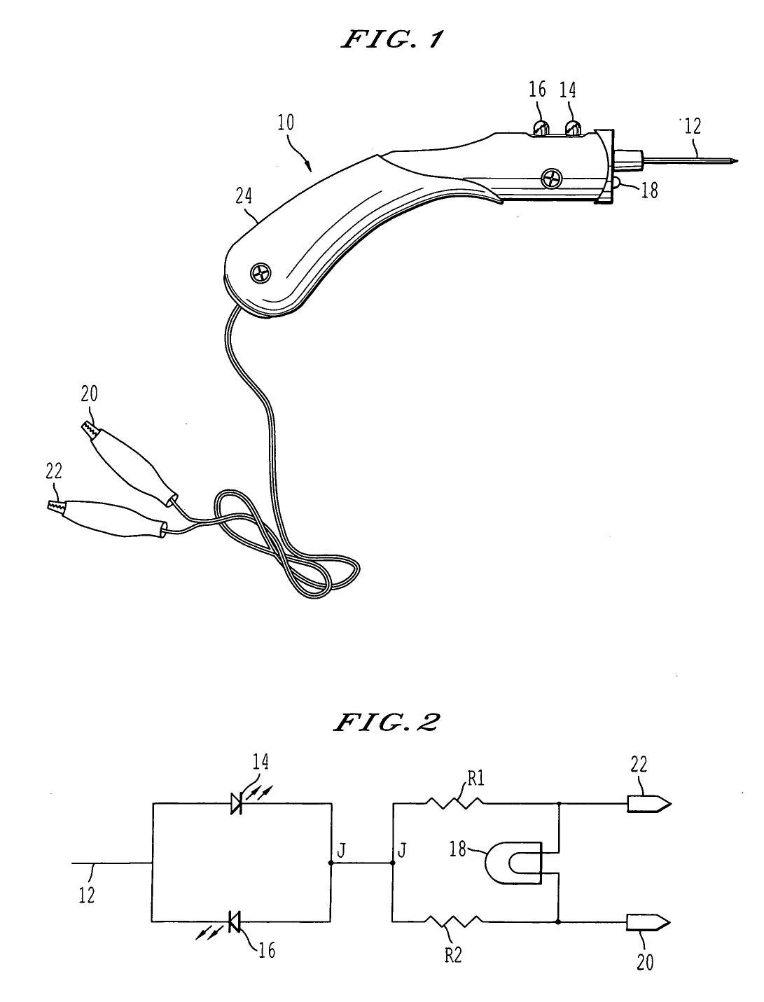

Referring now to the drawings, wherein like reference numerals designate identical or corresponding parts throughout the several views, and more particularly to FIG. 1 thereof, an external view of the electronic voltage polarity indicator 10 of the present invention is shown.

As shown in FIG. 1, the electronic voltage polarity indicator 10 includes a handle portion 24, which can be rubberized for an easy grip. Further, two connectors, such as alligator clips, 20, 22 are provided. Those two connectors are configured to contact to ground and to a positive power voltage source. In most vehicle environments that positive voltage source will be +12 volts, but could also be +6 volts, and variations in values of the following described circuit components can allow operation up to 50 volts nominal.

One of the benefits of the present invention is that the device of the present invention is fault-tolerant with respect to the connection of the connectors 20, 22. That is, with the structure in the present invention one of the connectors 20, 22 is connected to the voltage source and the other of the connectors is connected to ground, but it is irrelevant which one of the connectors 20, 22 is connected to the voltage source and which is connected to ground.

The connectors 20, 22 can be color coded, for example to be black and red so that the red connector clip 20 can be connected to a voltage source, e.g. a +12 volt power source, and the black connector clip 22 can be connected to ground in a vehicle. However, in this case the color coding is merely for a visual effect or for providing a comfort level to a user, but is not needed because the connectors 20, 22 can be connected to the voltage source and ground in either order.

Further, the electronic voltage polarity indicator 10 includes a probe 12 formed of a conductive metal material, two indicators 14 and 16, and an incandescent bulb 18. The incandescent bulb 18 provides two functions. A first function is to provide an indication when the connector clips 20, 22 are properly connected to a ground and a voltage source to indicate that the electronic voltage polarity indicator 10 is operating. A second function is that the incandescent bulb 18 can operate as a small flashlight to provide an illumination for the electronic voltage polarity indicator 10, for example when it is used in a darkened area such as under a dash in an automobile. Element 18 could also take the form of other light sources, such as a white LED.

Indicators 14 and 16 in a preferred embodiment are LEDs of two different colors that can provide an indication as to whether the probe element 12 is contacting an electrical surface with a positive polarity or a negative polarity. For example, the indicator 14 can be a red LED that when lit up represents that the probe element 12 is contacting a positive polarity electrical surface, and the indicator 16 can be a green LED that lights up when the probe element 12 is contacting a negative or ground electrical surface.

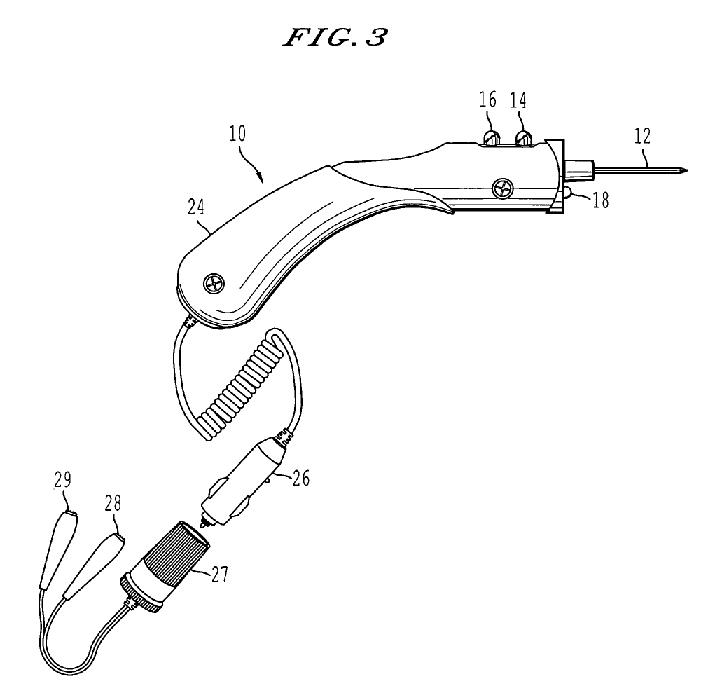

FIG. 2 shows the internal control circuitry in the electronic voltage polarity indicator 10 that provides the desired operation and indication.

As shown in FIG. 2, connected to the probe element 12 are the two LEDs 14, 16, which are connected in parallel to each other. At a junction point J of those two LEDs 14, 16 a connection is made to a circuit portion including two resistors R1, R2 and the incandescent bulb 18.

The circuitry in FIG. 2 operates as follows.

When the power terminal 22 is properly connected to power in the vehicle electrical system and the ground terminal 20 is properly connected to ground in the vehicle electrical system, the incandescent bulb 18 will glow to indicate those proper connections. Current will also flow through resistors R1 and R2 forming a Thevinin-equivalent voltage source at the junction J between the resistors R1 and R2. The Thevinin voltage will be half of the automobile supply voltage, and the current may be limited by a Thevinin-equivalent impedance of 500 ohms based on the selected component values.

If the probe element 12 is attached to a circuit presenting a return to ground through a low impedance, and thereby indicating the probe element 10 contacting a point with a negative polarity, light emitting diode 16 will be forward biased, and current will flow through LED 16 and LED 16 will glow to provide a green indication. The strength of the glow will be inversely related to the impedance of the ground path, and with properly selected component values anything less than 100 ohms will result in almost full brightness in the LED 16. The red LED 14, in this circumstance, will be reverse biased and will thereby not glow and be dark.

In a contrary situation, if the probe element 12 is attached to a point that returns to, e.g., +12 volts, i.e. an element having a positive polarity, diode 14 will conduct and thereby light up providing a red indication, and the green diode 16 will be dark.

If the probe element 12 connects to a point that alternates between power and ground as a voltage source, the LEDs 16 and 14 will glow alternately. If the frequency of alternation is high enough the LEDs 16 and 14 may both appear to glow steadily at the same time.

Thereby, evaluating which LED 16 or 14, or both, is glowing, i.e., whether the green LED 16 or the red LED 14 is, glowing, or if both are glowing, provides an indication to a user of the voltage polarity indicator 10 whether the point the probe element 12 is contacting a positive polarity, a negative polarity, or an alternating power source.

As noted above one of the benefits in the present invention is that it is irrelevant which one of the connectors 20, 22 is connected to power or ground. That is, the circuit of FIG. 2 operates properly if connector 22 is connected to ground and connector 20 is connected to the power, or vice versa. Further, one of the benefits of the circuit of FIG. 2 is its simplicity in that it allows either connection of connectors 20, 22 and requires very few components.

With such a circuit, and as noted above, an electronic voltage polarity indicator is provided that is simple to use, which is inexpensive to produce, which is safe to use, and which provides a simple to understand visual indication of a polarity of a contacted electrical surface.

The embodiment shown in FIG. 1 utilizes specific types of connectors 20, 22 to connect to ground and a power terminal, respectively. A second embodiment of the present invention shown in FIG. 3 incorporates the same structure of the probe element of FIG. 1, including the circuitry of FIG. 2, except for the connection to a power source. In FIG. 3 instead of utilizing two connector terminals 20, 22 a single power contact connector 26 to be plugged into a vehicle cigarette lighter is provided. As the proble element 10 may find particular application in use in vehicle environments, it may be helpful to utilize a power contact connector 26 for connection into a cigarette lighter. In this device when the power contact connector 26 is connected into a cigarette lighter the incandescent bulb 18 will glow. Otherwise the operation in this embodiment is the same as in the embodiment shown in FIG. 1.

Further, in this embodiment of FIG. 3 a further adaptor unit including a receptacle portion 27 and power terminals 28 and 29 can also be optionally provided. By utilizing the additional adaptor unit the receptacle portion 27 can receive the power contact connector 26 and then the terminals 28 and 29 can be connected to ground and power as in the first embodiment of FIG. 1. That is, by utilizing the additional adaptor unit with receptacle portion 27 and terminals 28, 29, the embodiment of FIG. 3 can be utilized in the same manner as the embodiment of FIG. 1.

It will be obvious to those skilled in the art that numerous additional modifications and variations of the present invention are possible in light of the above teachings. It is therefore to be understood that within the scope of the appended claims, the present invention may be practiced otherwise than as specifically described herein.

1. A test probe comprising:
(a) a probe element configured to contact an electrical surface;
(b) a circuit configured to determine if the electrical surface has a positive or negative polarity;
(c) an indicator configured to provide an indication of the determined positive or negative polarity;
(d) first and second connectors, either one of said first and second connectors configured to be connected to a power source and the other of said first and second connectors configured to be connected to ground; and
(e) a light source provided adjacent to the probe element and configured to provide a light output when the one of said first and second connectors is connected to the power source and the other of the first and second connectors is connected to the ground.

2. A test probe according to claim 1, wherein said circuit comprises:
(b 1) first and second resistors connected to a same junction point.

3. A test probe according to claim 2, wherein said first connector is connected in series with said first resistor and said second connector is connected in series with said second resistor.

4. A test probe according to claim 2, further comprising:
(d) a power connector configured to be inserted into a cigarette lighter receptacle, to provide power to said test probe.

5. A test probe according to claim 4, further comprising:
(e) an adaptor including (e1) a receptacle configured to receive said power connector and
(e2) first and second terminals electrically connected to said receptacle.

6. A test probe according to claim 1, wherein said indicator comprises:
(c1) a first indication element configured to indicate the determined positive polarity; and
(c3) a second indication element configured to indicate the determined negative polarity.

7. A test probe according to claim 6, wherein said first indication element includes a light emitting diode (LED) of a first color and said second indication element includes an LED of a second color.

8. A test probe according to claim 2, wherein said indicator comprises:
(c1) a first indication element configured to indicate the determined positive polarity; and
(c3) a second indication element configured to indicate the determined negative polarity.

9. A test probe according to claim 8, wherein said first indication element includes a light emitting diode (LED) of a first color and said second indication element includes an LED of a second color.

10. A test probe according to claim 3, wherein said indicator comprises:
(c1) a first indication element configured to indicate the determined positive polarity; and
(c2) a second indication element configured to indicate the determined negative polarity.

11. A test probe according to claim 4, wherein said indicator comprises:
(c1) a first indication element configured to indicate the determined positive polarity; and
(c2) a second indication element configured to indicate the determined negative polarity.

12. A test probe according to claim 10, wherein said first indication element includes a light emitting diode (LED) of a first color and said second indication element includes an LED of a second color.

13. A test probe according to claim 11, wherein said first indication element includes a light emitting diode (LED) of a first color and said second indication element includes an LED of a second color.

14-16. (canceled)

17. A test probe comprising:
(a) means for contacting an electrical surface;
(b) means for determining if the electrical surface has a positive or negative polarity;
(c) means for providing a first indication of the determined positive or negative polarity; and
(d) first and second means for connecting, either one of said first and second means for connecting for providing a connection to a power source and the other of said first and second means for connecting for providing a connection to ground;
(e) means for providing a light output, provided adjacent to the means for contacting an electrical surface, when the one of the first and second means is connected to the power source and the other of the first and second means is connected to the ground.

18. (canceled)
